(19) United States
(12) Patent Application Publication
(10) Pub. No.: US 2012/0120756 A1
(43) Pub. Date: May 17, 2012

(54) MODULAR MIXER

(75) Inventors: Jens Hepperle, Koln (DE); Karl-Robert Boos, Burscheid (DE); Frank Herbstritt, Alzey (DE)

(73) Assignees: EHRFELD MIKROTECHNIK BTS GMBH, Wendelsheim (DE); BAYER TECHNOLOGY SERVICES GMBH, Leverkusen (DE)

(21) Appl. No.: 13/266,055

(22) PCT Filed: Apr. 15, 2010
(86) PCT No.: PCT/EP2010/002309

§ 371 Date: Jan. 27, 2012

(30) Foreign Application Priority Data
Apr. 24, 2009 (DE) 10 2009 018 539.9

(51) Int. Cl. B01F 5/06; B81B 1/00

(52) U.S. Cl. 366/336

(57) ABSTRACT

The invention relates to modular mixers for applications in modular microprocess technology.

The invention relates to modular mixers for applications in modular microprocess technology.

In recent decades, microprocess technology or microreaction technology has increasingly become an important tool in chemical research and development. The reason for this is the requirement of the market for the development of new products and improved processes in ever shorter time periods.

Modular microprocess technology affords the possibility of joining together different microprocess modules according to a modular principle to form a complete production plant on a very small scale. In addition to the resulting high flexibility and the reduction in waste on account of the smaller quantities of chemicals that are required for experiments in microreaction plants, microprocess technology has immediate advantages for carrying out chemical processes: microstructured apparatus has a very large surface-to-volume ratio. For this reason, heat and mass transfer processes, for example, can be considerably intensified.

Modular microreaction systems are available commercially, e.g. from Ehrfeld Mikrotechnik BTS GmbH. The commercially available modules include mixers, reactors, heat exchangers, sensors and actuators and many others.

Static mixers have established themselves as mixers in microprocess technology. Whereas in the case of dynamic mixers a mixture is homogenized by way of moving organs, such as e.g. stirrers, in the case of static mixers the flow energy of the fluid is exploited: a conveying unit (e.g. a pump) pushes the liquid through a tube provided with static mixing internals, with the liquid following the main flow axis being subdivided into substreams, which, depending on the type of internals, are swirled together and mixed. An overview of various kinds of static mixers, as are used in conventional process technology, is given, for example, in the article “Statische Mischer and ihre Anwendungen” [Static mixers and their applications], M. H. Pahl and E. Muschelknautz, Chem.-Ing.-Techn. 52 (1980) No. 4, pp. 285-291. SMX mixers are mentioned here as an example of static mixers (cf. U.S. Pat. No. 4,062,524). They consist of two or more grids, which are perpendicular to one another, of parallel strips which are connected together at their points of intersection and are positioned at an angle to the main flow direction of the material being mixed, in order to divide the liquid into substreams and to mix it. A single mixing element is unsuitable as a mixer because mixing only takes place in a preferential direction transversely to the main flow direction. Therefore, a plurality of mixing elements, which are rotated through 90° with respect to one another, must be arranged in series.

An example of a static micromixer is the faceted mixer described in DE20219871U1.

By reducing the size of the characteristic dimensions, mixing processes, in addition to heat transfer processes, also proceed much more quickly in micromixers than in conventional mixers. Thus, some of the process speeds in micromixers are several powers of ten higher than in conventional plants and the mixing sections are reduced to a few millimetres.

However, the small ducts in micromixers tend to become blocked and therefore are not suitable for all chemical processes. Thus, for example, the mixer described in U.S. Pat. No. 5,904,424 has narrow ducts having tight fluid deflections in which deposits that can lead to a blockage can form. Furthermore, the throughputs and/or residence times of commercially available micromixers are limited on account of the small effective volume provided. If chemical reactions having small reaction speeds with respect to the available residence time are carried out in the micromixers, then a plurality of micromixers may have to be connected in series in order that there is a sufficient residence time available for bringing the reaction to completion. A series connection of a plurality of micromixers has a number of disadvantages, however. Firstly, the series connection of a plurality of micromixers leads to a high pressure loss. In addition, the individual micromixers, and in particular the connecting points, have to be sealed off from the outside world, and this means increasing complexity with an increasing number of micromixers. Further, a high number of micromixers also causes correspondingly high investment costs. Furthermore, the known micromixers as a rule do not have a variable mixing action.

It would be desirable to have available a mixing module which can be adapted to the respective chemical process. In particular, it would be desirable to have available mixing modules which allow higher throughputs and/or longer residence times than the commercially available micromixers.

Finally, it would be desirable to have available the established mixers from conventional production plants also on the micro scale, in order to simplify the scaling up of a process in the micro scale to the industrial scale.

On the basis of the known prior art, the object is set of providing a mixing module which is compatible with a commercially available modular microreaction system, which can be combined with further modules of a modular commercially available microreaction system to form a microreaction plant, which can be adapted to various chemical processes, which allows a higher throughput and/or a longer residence time than the commercially available systems, which has less of a tendency to become blocked, which can be produced in a cost-effective manner, and which can be used intuitively.

Therefore, the subject matter of the present invention is a mixing module at least comprising a basic body having an inlet and an outlet at opposite end faces of the basic body and a duct between the inlet and the outlet, characterized in that the duct provides a volume in the range from 0.2 ml to 3 ml for the reversible accommodation of a variable mixing body.

According to the invention, the mixing module comprises a basic body having an inlet and an outlet at opposite end faces of the basic body. The basic body is preferably designed as a polyhedral body, particularly preferably as a cuboid having optionally rounded corners. A polyhedron is a body which is bounded by planar polygons. A polygon is obtained by at least three different points in a drawing plane being connected together by lines such that a closed figure results. Triangles, squares and hexagons are example of polygons that are known from everyday life. All faces which delimit the basic body of the mixing module towards the outside are designated end faces here.

The opposite end faces of the basic body, which have an inlet or an outlet, are preferably arranged parallel to one another. The inlet and the outlet are preferably formed in a round manner. They preferably have the same diameter. Between the inlet and the outlet, a duct extends through the basic body and connects the inlet and the outlet together.

The duct serves to reversibly accommodate an interchangeable mixing body which is formed in a geometrically variable manner.

To this end, the duct makes available a volume in the range from 0.2 ml to 3 ml, preferably in the range from 0.25 ml to 2.5 ml, particularly preferably in the range from 0.3 ml to 1.5 ml.

To interchangeably accommodate is understood to mean that a mixing body is introduced into the duct and, once the mixing module according to the invention has been used, can be removed again. A geometrically variable mixing body is understood to mean that the mixing module according to the invention is not restricted to a specific mixing body, but rather that various (variable) mixing bodies can be introduced into the duct. The mixing body according to the invention thus makes available static mixers, as are used in conventional process technology, also for microprocess technology or microreaction technology.

The duct is preferably in the form of a cylinder. A cylinder is a body which is bounded by two identical parallel, planar faces (bottom and top face) and a lateral surface formed by parallel straight lines. It results from a planar surface or curve being pushed along a straight line which does not lie in this plane. A specific embodiment of a cylinder is a circular cylinder. A cylindrical duct within the meaning of the present invention is accordingly a space, the external boundary of which corresponds to the lateral surface of a cylinder. Since a duct according to the invention between the inlet and the outlet is designed to be continuous, in the case of a cylindrical duct there is no bottom and top face corresponding to a cylindrical body. The cylindrical duct preferably has an elliptical, round or n-gonal cross section, with n being an integer greater than or equal to 3. Particularly preferred is a round or rectangular cross section of the duct.

In the duct there may be projections which serve for fixing the mixing body. The duct has a smaller diameter than or the same diameter as the inlet and the outlet. The duct extends preferably perpendicularly to the two end faces which contain the inlet and the outlet.

The duct serves for reversibly accommodating a mixing body. Suitable as mixing body are static mixers known from the prior art, e.g. Kenics mixers or SMXL mixers, or else novel mixing elements which are provided to be inserted into flow channels. A selection of static mixing bodies that can be used can be found for example in M. H. Pahl (ed.): “Mischen von Kunststoff- and Kautschukprodukten” [Mixing of plastics and rubber products], VDI-Verlag, 1993, pp. 351-391. An SMX mixer is preferably used as mixing body.

The basic body consists of a chemically inert material, e.g. of plastic, glass or a metal or alloy. Preferably, it is made from an A4 stainless steel (e.g. DIN 1.4571 or 1.4401) or Hastelloy C 276 (DIN 2.4819).

Optionally, the mixing module according to the invention has covers, which can be connected reversibly (i.e. releasably) to the two end faces which contain the inlet or the outlet. Each cover has a through-hole which forms a continuous duct with the inlet and the outlet. The covers serve to reduce or extend the cross section of the inlet or outlet and/or to fix the mixing body within the mixing module according to the invention. Accordingly, the lids have a through-hole diameter which is smaller than the diameter of the inlet or of the outlet.

The covers are connected to the basic body preferably via a reversible plug-in, screw or clamping connection. To this end, the covers, in a preferred embodiment, have through-holes for guiding through plug-in elements or screws. The basic body has corresponding holes for accommodating the plug-in elements or screws by way of which the basic body and the covers are connected. Further, the covers have on their connecting surfaces to the basic body means for accommodating a seal which is preferably in the form of an annular recess (sealing groove) around the through-hole.

In a preferred embodiment, the covers each have on the side facing the inlet or the outlet an annular projection which can be inserted into the inlet or the outlet and serves for centering the respective cover with respect to the basic body. If the diameter of the duct for accommodating the mixing body is smaller than the diameter of the inlet or outlet, the annular projection of the cover terminates preferably flush with the projection, which is formed by the different diameters of inlet or outlet and the duct for accommodating the mixing body.

The covers can be made from the same material as the basic body or be made from a different material. They are preferably made from the same material as the basic body.

The mixing module is designed such that it can be connected reversibly to other modules of a modular microreaction system. By inserting different mixing bodies, the mixing action of the mixing module according to the invention and the pressure required for conveying fluid can be designed to be variable with the same apparatus dimensions.

Furthermore, the mixing module according to the invention has at least one bottom plate for positioning the mixing module on a base plate. The at least one bottom plate and the basic body can be produced from one piece or they can be different components of the mixing module. Preferably, the at least one bottom plate is configured as a separate component which can be connected to the basic body via at least one releasable connection. The at least one bottom plate has means which allow the mixing module according to the invention to be positioned on a base plate. As a result, the mixing module can be connected to further modules of a modular microreaction system to form a more complex plant. Preferably, the bottom plate has guide elements which engage in grooves in the base plate and orient the mixing module on the base plate. Bottom plates can be made from the same material as the basic body. In the case of a preferred thermal decoupling of the basic body and the base plate, bottom plates are made from a material which allows the thermal decoupling of the mixing module and the base plate. For example, a polyaryl ether ketone, such as the polymer VICTREX® PEEK from Victrex Plc is suitable as material for the base plate.

In the case of a heated base plate, the bottom plates according to the invention are preferably made from a material which allows thermal coupling of the mixing module to the base plate. For example, aluminium is suitable as material for the bottom plate.

The mixing module according to the invention is connected to further micromodules of a modular microreaction system preferably via a force-fitting connection. As is stated for example on page 1-5 of the brochure “Modulare Mikroreaktionstechnik” [Modular microreaction technology] from Ehrfeld Mikrotechnik BTS GmbH dated Aug. 5, 2008, the individual modules are arranged on a common base plate by means of one or more bottom plates. Arranged between the individual modules are sealing discs which seal off the connecting points between two adjacent modules from the outside world. Perfluorinated elastomers such as perfluoro rubber (FFKM) or Teflon (PTFE) can be used as sealing materials. Clamping modules are used at the two ends of a row of modules arranged alongside one another, said clamping modules having a punch which can be moved by means of a screw towards the adjacent module. This makes it possible to clamp the modules within a row together and to seal off the connecting points with respect to the outside world.

The present invention furthermore relates to a device at least comprising a mixing module according to the invention and at least one mixing body. The at least one mixing body is introduced into the duct in the mixing module. Suitable mixing bodies are the static mixers known from the prior art, as are described by way of example, but not fully, in M. H. Pahl (ed.): “Mischen von Kunststoff- and Kautschukprodukten” [Mixing of plastics and rubber products], VDI-Verlag, 1993, pp. 351-391.

The present invention furthermore relates to a device comprising at least one mixing module according to the invention and an input module. The mixing module and input module are releasably connected together preferably via a sealing means.

The input module serves to bring different fluid streams together and/or to supply fluid streams to the mixing module according to the invention.

The input module comprises a basic body, which is preferably polyhedral. Attached to the end faces of the basic body are inlets. These are preferably attached to different end faces. The basic body of an input module has at least two inlets, with preferred embodiments having 2 or 3 inlets. The inlets have preferably a round cross section. The inlets merge into ducts which run towards a common end face of the basic body. Some or all of the ducts can run together within the basic body to form a single duct which opens into a single outlet at said end face. Likewise, it is conceivable for the ducts not to run together in the basic body but to open into separate outlets at the common end face. Preferably, all the ducts are formed in a cylindrical manner. Preferably, the inlet ducts have the same diameter and the outlet ducts likewise have the same diameter, wherein the diameter of the inlet ducts is preferably larger than the diameter of the outlet ducts.

The basic body of the input module is made from a chemically inert material, e.g. of plastic, glass or a metal or alloy. It is preferably made from an A4 stainless steel (e.g. DIN 1.4571 or 1.4401) or Hastelloy C 276 (DIN 2.4819).

The input module comprises furthermore at least one bottom plate for positioning the input module on a base plate. The bottom plate and the basic body of the input module can be produced from one piece or they can be two different components. Preferably, the bottom plate is configured as a separate component which can be connected to the basic body via at least one releasable connection. Preferably, the bottom plate and the basic body are connected together via plug-in elements, screws or equivalent fastening means. In a preferred embodiment, the basic body has holes for accommodating plug-in elements or screws and the bottom plate has through-holes so that plug-in elements or screws can be guided through the through-holes in the bottom plate and be plugged or screwed into the holes in the basic body. The bottom plate has means which allow positioning on a base plate. As a result, the input module can be connected to further modules of a modular microreaction system, in particular to the mixing module according to the invention, to form a plant. Preferably, the bottom plate has guide elements which engage in grooves in the base plate and orient the mixing module on the base plate.

The bottom plate can be made from the same material as the basic body. Preferably, the bottom plate is made from a material which allows the thermal decoupling of the input module and the base plate, such as VICTREX® PEEK from Victrex Plc, for example. In the case of heated base plate, the bottom plates according to the invention are preferably made from a material which allows thermal coupling of the mixing module to the base plate. Aluminium is suitable for example as the material for the bottom plate.

In the device according to the invention, the mixing module and the input module are connected together via a sealing means, i.e. a sealing means is applied between the mixing module and the input module and seals off the connecting point between the mixing module and the input module from the outside world. As sealing means, use can be made, for example, of a ring of a perfluorinated elastomer such as perfluoro rubber (FFKM) or Teflon (PTFE). Likewise, it is conceivable to use the sealing discs used in the modular microreaction system from Ehrfeld Mikrotechnik BTS GmbH. The input module and mixing module are attached to a common base plate and are connected together preferably in a force-fitting manner, e.g. in the manner described above for the modular microreaction system from Ehrfeld Mikrotechnik BTS GmbH, by means of clamping via clamping modules.

The present invention furthermore relates to a device at least comprising a mixing module, an input module and a mixing body. The mixing body is inserted into the duct in the mixing module. The mixing module and the input module are connected together releasably, preferably in a force-fitting manner.

The present invention also relates to the use of a mixing module, of a device comprising a mixing module and a mixing body, and of a device comprising a mixing module, a mixing body and an input module in a preferably modular microreaction system.

### EXAMPLES

The invention is explained in more detail below with reference to examples, but without being limited thereby.

### Example 1

### Mixing Module (6 mm)

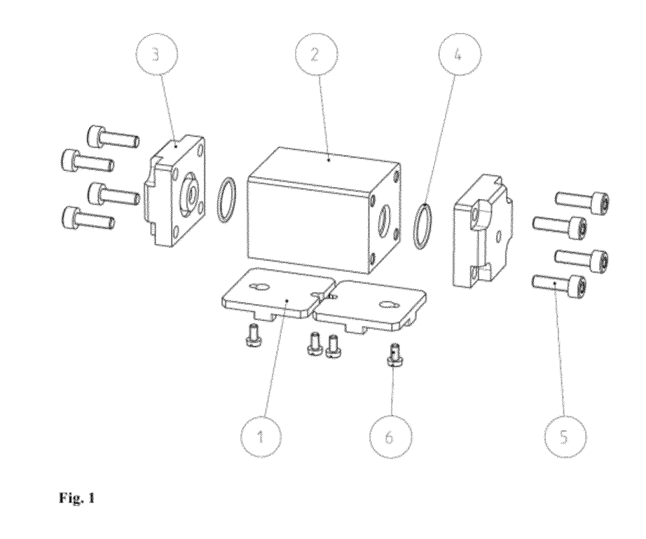

FIG. 1 shows an exploded view of a preferred embodiment of a mixing module according to the invention. The mixing module comprises a basic body (2), two covers (3) and two bottom plates (1). Sealing means in the form of sealing rings (4) are inserted between the covers (3) and the basic body (2). The covers are connected releasably to the basic body (2) via screw connections (5). The bottom plates (1) are connected releasably to the basic body (2) by means of screws (6) or other plug-in means.

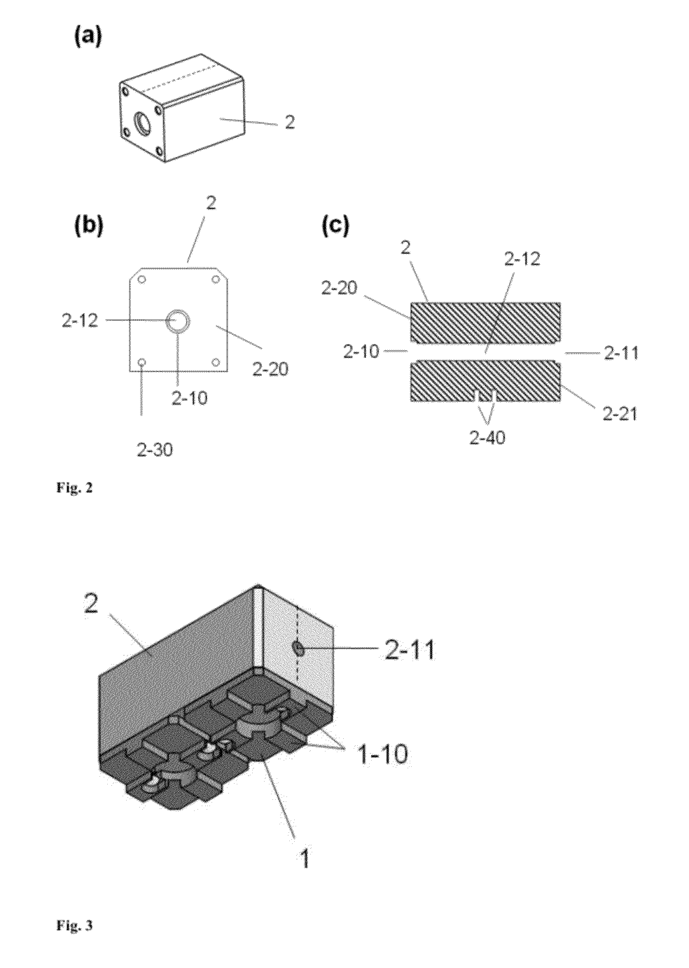

FIG. 2 shows the basic body (2) of the mixing module according to the invention, (a) in a perspective view, (b) from the front and (c) in cross section along the dashed line illustrated in FIG. 2(a).

Two opposite end faces (2-20, 2-21) have holes which form an inlet (2-10) and an outlet (2-11). Provided between the inlet (2-10) and the outlet (2-11) is a duct which connects the inlet and the outlet together. This duct (2-12) serves to accommodate a mixing body, in the present case to accommodate an SMX mixer from Sulzer having a diameter of 6 mm or another cylindrical mixer (e.g. Kenics). The diameter of the duct is accordingly 6.1 mm. The volume provided by the duct is approximately 0.9 ml.

Provided at the end faces are threaded holes, by means of which it is possible to attach covers to the end faces. Located on the underside of the basic body (2) are further holes, by means of which it is possible to attach bottom plates. The bottom plates (6) illustrated in FIG. 1 and FIG. 3, for example, can be attached here as bottom plates.

### Example 2

### Mixing Module (3 mm)

FIG. 3 shows a perspective view of a further preferred embodiment of the mixing module according to the invention. FIG. 3 shows the basic body (2), the outlet (2-11) at one of the end faces of the basic body and the bottom plates (1). The bottom plates have guide elements (1-10), with which the mixing module according to the invention can be connected to a base plate and oriented on the base plate.

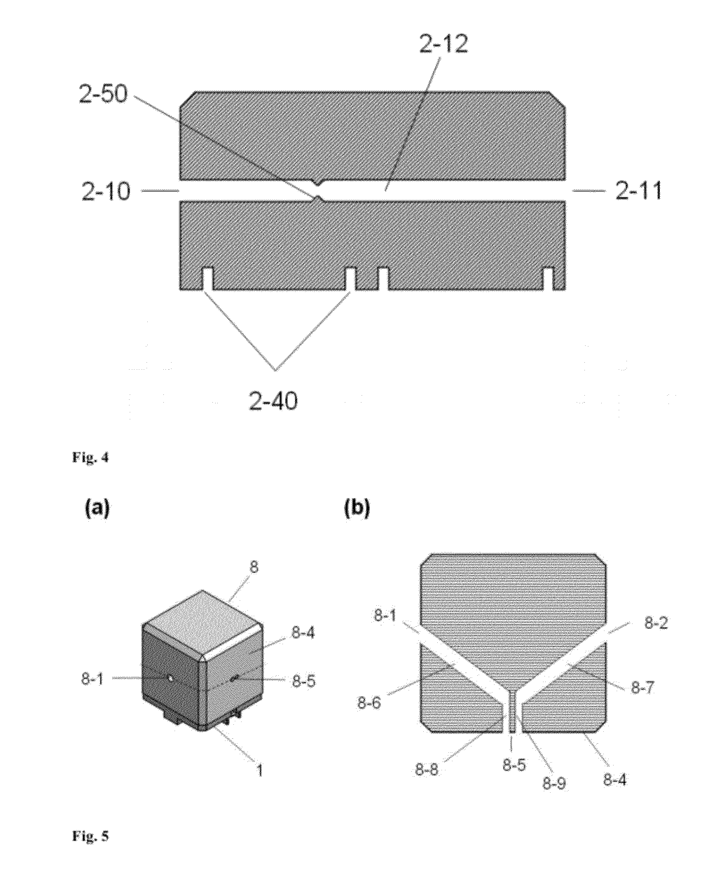

FIG. 4 shows a cross section through the basic body (2) of the mixing module according to the invention along the dashed line shown in FIG. 3. The inlet (2-10) and the outlet (2-11) are connected together via a duct (2-12). The duct is formed by two holes which proceed from the inlet and the outlet. At the point where the holes meet one another, there are projections, which can serve to fix a mixing body which is inserted into the duct. The basic body further has holes (2-40) in the bottom in order that bottom plates can be fastened to the basic body, as shown in FIG. 3.

The duct serves to accommodate a mixer having a diameter of 3 mm.

### Example 3

### Input Module for Two Streams

FIG. 5 shows a preferred embodiment of an input module according to the invention for bringing together two fluid streams, (a) in a perspective illustration, (b) in cross section along the dashed line shown in FIG. 5(a). The input module has a basic body (8) and a bottom plate (1). Located in different end faces of the basic body are two inlets (8-1) and (8-2). Proceeding therefrom are ducts (8-6) and (8-7), which extend obliquely in the direction of a common end face (8-4). The end face (8-4) has an outlet (8-5), from which there proceed two ducts (8-8) and (8-9) which run together with the ducts (8-6) and (8-7), respectively, in the basic body.

### Example 4

### Input Module for Three Streams

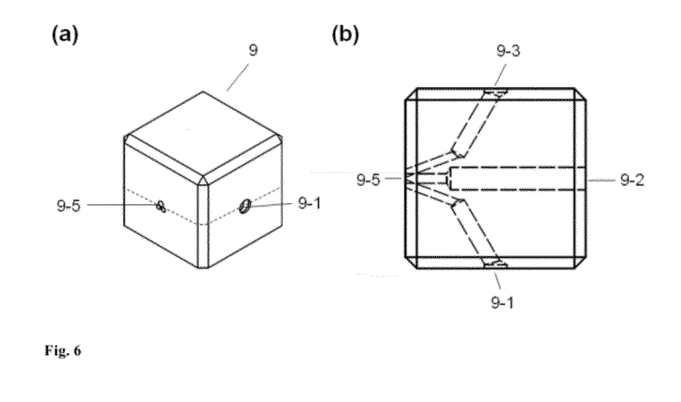

FIG. 6 shows the basic body (9) of a further preferred embodiment of an input module according to the invention for bringing together three fluid streams, (a) in a perspective illustration, (b) in cross section along the dashed line shown in FIG. 6(a). Located at three different end faces are inlets (9-1), (9-2) and (9-3). From these inlets, ducts (inlet ducts) proceed in the direction of a common end face, in which there is located an outlet (9-5). Three ducts (outlet ducts) proceed from the outlet (9-5) in the direction of the inlet ducts. In each case one outlet duct meets one inlet duct in the basic body (9) of the input module.

### REFERENCE SIGNS

1 Bottom plate
1-10 Guide elements
2 Basic body of a mixing module
2-10 Inlet in the mixing module
2-11 Outlet in the mixing module
2-12 Duct for accommodating a mixing body
2-20 End face of a mixing module
2-21 End face of a mixing module
2-30 Threaded hole
2-40 Hole
2-50 Projection
3 Cover
4 Sealing means
5 Screws
6 Plug-in elements
8 Basic body of an input module for two streams
8-1 Inlet in the input module
8-2 Inlet in the input module
8-4 End face of the input module
8-5 Outlet in the input module
8-6 Inlet duct
8-7 Inlet duct
8-8 Outlet duct
8-9 Outlet duct
9 Basic body of an input module for three streams
9-1 Inlet in the input module
9-2 Inlet in the input module
9-3 Inlet in the input module
9-5 Outlet in the input module

1. A modular mixing module comprising
a basic body having an inlet and an outlet at opposite end faces of the basic body and
a duct between the inlet and the outlet,
wherein the duct provides a volume in the range from 0.2 ml to 3 ml for the reversible accommodation of a variable, cylindrical mixing body.

2. The mixing module according to claim 1, further comprising
in each case a cover for the end face having the inlet and a cover for the end face having the outlet, wherein the covers are reversibly connected to the end faces by at least one releasable connection, wherein each cover has a respective hole which forms a continuous duct with the inlet and the outlet.

3. The mixing module according to claim 2, further comprising sealing means between the covers and the end faces of the housing.

4. The mixing module according to claim 1, further comprising at least one bottom plate for positioning the mixing module on a base plate.

5. The mixing according to claim 1, wherein the at least one bottom plate can be reversibly connected to the basic body via at least one releasable connection and has guide elements which engage in grooves in the base plate and orient the mixing module on the base plate.

6. A device comprising a mixing module according to claim 1, comprising at least one mixing body which is reversibly introduced into the duct in the mixing module.

7. A device according to claim 6, further comprising at least one input module and a sealing means between the at least one mixing module and the input module, wherein the input module comprises a basic body which has at least two inlets which are arranged at different end faces of the input module and from which there proceed ducts which run through the basic body in the direction of a common end face of the input module.

8. A device according to claim 7, wherein the mixing module and the input module are connected together in a force-fitting manner on a common base plate.

9. A method for using a mixing module according to claim 1, in a modular microreaction system.

10. A method for using of a mixing module according to claim 6 a modular microreaction system.
